(19) United States
(12) Patent Application Publication
(10) Pub. No.: US 2025/0081485 A1
(43) Pub. Date: Mar. 6, 2025

(54) JUNCTION BARRIER SCHOTTKY DIODE

(71) Applicant: TDK CORPORATION, Tokyo (JP)

(72) Inventors: Jun ARIMA, Tokyo (JP); Minoru FUJITA, Tokyo (JP); Katsumi KAWASAKI, Tokyo (JP); Jun HIRABAYASHI, Tokyo (JP)

(21) Appl. No.: 18/891,242

(22) Filed: Sep. 20, 2024

Related U.S. Application Data
(63) Continuation of application No. PCT/JP2023/000366, filed on Jan. 11, 2023.

(30) Foreign Application Priority Data
Mar. 23, 2022 (JP) 2022-047239

(51) Int. Cl. H01L 29/872; H01L 29/24

(52) U.S. Cl. CPC H10D 8/60; H10D 62/80

(57) ABSTRACT

Disclosed herein is a junction barrier Schottky diode that includes a semiconductor substrate, a drift layer provided on the semiconductor substrate, an anode electrode and a p-type semiconductor layer each contacting the drift layer, an n-type semiconductor layer contacting the anode electrode and the drift layer, a metal layer provided between the n-type semiconductor layer and the p-type semiconductor layer, and a cathode electrode contacting the semiconductor substrate.

### BACKGROUND OF THE ART

The present disclosure relates to a junction barrier Schottky diode and, more particularly, to a junction barrier Schottky diode.

A Schottky barrier diode is a rectifying element utilizing a Schottky barrier generated due to bonding between metal and a semiconductor and is lower in forward voltage and higher in switching speed than a normal diode having a PN junction. Thus, the Schottky barrier diode is sometimes utilized as a switching element for a power device.

When the Schottky barrier diode is utilized as a switching element for a power device, it is necessary to ensure a sufficient backward withstand voltage, so that silicon carbide (SiC), gallium nitride (GaN), or gallium oxide (Ga₂O₃) having a larger band gap is sometimes used in place of silicon (Si). Among them, gallium oxide has a very large band gap (4.8 eV to 4.9 eV) and a large breakdown field of about 8 MV/cm, so that a Schottky barrier diode using gallium oxide is very promising as the switching element for a power device. An example of the Schottky barrier diode using gallium oxide is described in JP 2019-036593 A.

JP 2019-036593 A discloses a junction barrier Schottky diode having a structure in which a plurality of trenches provided in a gallium oxide layer are filled with a p-type semiconductor material. By thus providing a plurality of trenches in the gallium oxide layer and filling the plurality of trenches with a p-type semiconductor material, a mesa region positioned between the trenches becomes a depletion layer upon application of a backward voltage, so that a channel region of a drift layer is pinched off. Thus, a leak current upon application of the backward voltage can be significantly reduced.

However, the junction barrier Schottky diode described in JP 2019-036593 A has only limited areas that function as a Schottky barrier diode, which poses a problem in that an ON-resistance during the time from when the Schottky barrier diode is turned ON to when a forward current flows in a pn-junction part is high.

### SUMMARY

It is desirable to reduce the ON-resistance of a junction barrier Schottky diode.

A junction barrier Schottky diode according to the present disclosure includes: a semiconductor substrate; a drift layer provided on the semiconductor substrate; an anode electrode and a p-type semiconductor layer each contacting the drift layer; an n-type semiconductor layer contacting the anode electrode and the drift layer; a metal layer provided between the n-type semiconductor layer and the p-type semiconductor layer; and a cathode electrode contacting the semiconductor substrate.

### BRIEF DESCRIPTION OF THE DRAWINGS

FIG. 1A is a schematic plan view illustrating the configuration of a junction barrier Schottky diode 1 according to a first embodiment of the present disclosure.

FIG. 1B is a schematic cross-sectional view taken along the line A-A in FIG. 1A.

FIGS. 2A and 2B are energy band diagrams of the junction barrier Schottky diode 1, where FIG. 2A illustrates an energy band along the first current path P1, and FIG. 2B illustrates an energy band along the second current path P2.

FIG. 3 is a graph illustrating the relation between a forward voltage VF and a forward current IF.

FIG. 4 is a schematic plan view illustrating the configuration of a junction barrier Schottky diode according to a first modification.

FIG. 5 is a schematic plan view illustrating the configuration of a junction barrier Schottky diode according to a second modification.

FIG. 6 is a schematic plan view illustrating the configuration of a junction barrier Schottky diode according to a third modification.

FIG. 7A is a schematic plan view illustrating the configuration of a junction barrier Schottky diode according to a fourth modification.

FIG. 7B is a schematic cross-sectional view taken along the line A-A in FIG. 7A.

FIG. 8 is a schematic cross-sectional view illustrating the configuration of a junction barrier Schottky diode 2 according to a second embodiment of the present disclosure.

FIG. 9 is an energy band diagram of the junction barrier Schottky diode 2, which illustrates an energy band along the second current path P2 according to a first example.

FIG. 10 is an energy band diagram of the junction barrier Schottky diode 2, which illustrates an energy band along the second current path P2 according to a second example.

FIG. 11A is a schematic plan view illustrating the configuration of a junction barrier Schottky diode 3 according to a third embodiment of the present disclosure.

FIG. 11B is a schematic cross-sectional view taken along the line A-A in FIG. 11A.

FIG. 12 is a schematic plan view illustrating the configuration of a junction barrier Schottky diode according to a fifth modification.

FIG. 13 is a schematic plan view illustrating the configuration of a junction barrier Schottky diode according to a sixth modification.

FIG. 14A is a schematic plan view illustrating the configuration of a junction barrier Schottky diode according to a seventh modification.

FIG. 14B is a schematic cross-sectional view taken along the line A-A in FIG. 14A.

FIG. 15 is a schematic cross-sectional view illustrating the configuration of a junction barrier Schottky diode according to an eighth modification.

FIG. 16 is a schematic cross-sectional view illustrating the configuration of a junction barrier Schottky diode according to a ninth modification.

FIG. 17 is a schematic cross-sectional view illustrating the configuration of a junction barrier Schottky diode according to a tenth modification.

FIG. 18 is a schematic cross-sectional view illustrating the configuration of a junction barrier Schottky diode according to an eleventh modification.

FIG. 19A is a schematic plan view illustrating the configuration of a junction barrier Schottky diode according to a twelfth modification.

FIG. 19B is a schematic cross-sectional view taken along the line A-A in FIG. 19A.

FIG. 20 is a schematic cross-sectional view illustrating the configuration of a junction barrier Schottky diode according to an thirteenth modification.

### DETAILED DESCRIPTION OF THE EMBODIMENTS

Hereinafter, some embodiments of the present disclosure will be described in detail with reference to the accompanying drawings.

### First Embodiment

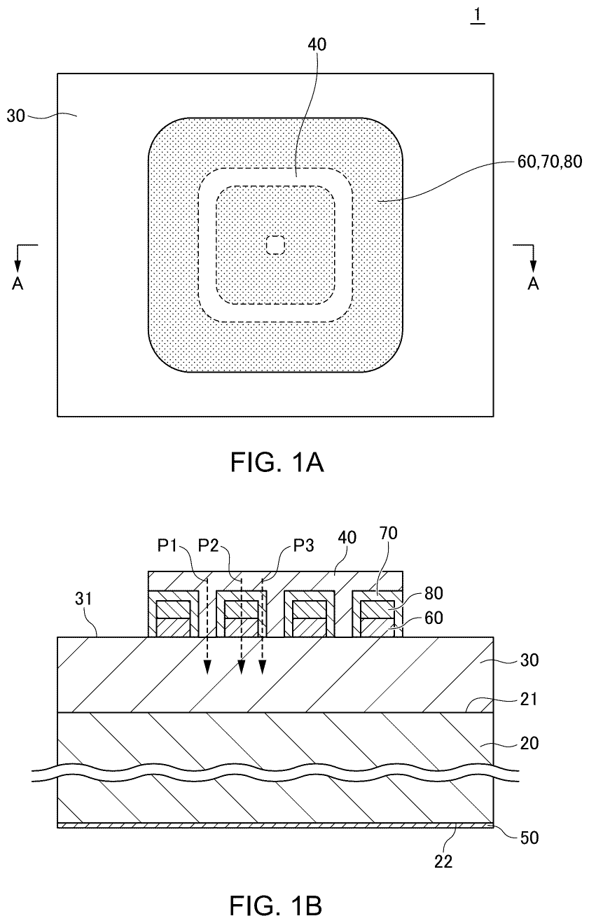

FIG. 1A is a schematic plan view illustrating the configuration of a junction barrier Schottky diode 1 according to a first embodiment of the present disclosure and FIG. 1B is a schematic cross-sectional view taken along the line A-A in FIG. 1A.

As illustrated in FIGS. 1A and 1B, the junction barrier Schottky diode 1 according to the first embodiment has a semiconductor substrate 20 and a drift layer 30, both of which are made of gallium oxide (β-Ga₂O₃). The semiconductor substrate 20 and drift layer 30 are each introduced with silicon (Si) or tin (Sn) as an n-type dopant. The concentration of the dopant is higher in the semiconductor substrate 20 than in the drift layer 30, whereby the semiconductor substrate 20 and the drift layer 30 function as an n⁺ layer and an n⁻ layer, respectively. The impurity concentration of the semiconductor substrate 20 is, for example, about 1×10¹⁸ cm⁻³, and the impurity concentration of the drift layer 30 is, for example, about 1×10¹⁶ cm⁻³.

The semiconductor substrate 20 is obtained by cutting a bulk crystal formed using a melt-growing method and has a thickness of about 250 μm. The planar size of the semiconductor substrate 20 is not particularly limited and is generally selected in accordance with the amount of current flowing in the element. For example, when the maximum amount of forward current is about 20A, the planar size may be set to about 2.4 mm×2.4 mm.

The semiconductor substrate 20 has an upper surface 21 positioned on the upper surface side in a mounted state and a back surface 22 positioned on the lower surface side in a mounted state. The drift layer 30 is formed on the entire upper surface 21. The drift layer 30 is a thin film obtained by epitaxially growing gallium oxide on the upper surface 21 of the semiconductor substrate 20 using a reactive sputtering method, a PLD method, an MBE method, an MOCVD method, or an HVPE method. The film thickness of the drift layer 30 is not particularly limited and is generally selected in accordance with the backward withstand voltage of the element. For example, in order to ensure a withstand voltage of about 600 V, the film thickness may be set to about 7 μm.

There are formed, on the upper surface 31 of the drift layer 30, a p-type semiconductor layer 60 and a metal layer 80 which are stacked in this order, an n-type semiconductor layer 70 covering the surface of the stacked body of the p-type semiconductor layer 60 and metal layer 80, and an anode electrode 40 covering the n-type semiconductor layer 70 and being brought into Schottky contact with the drift layer 30. The anode electrode 40 is formed of metal such as platinum (Pt), palladium (Pd), gold (Au), nickel (Ni), molybdenum (Mo), or Copper (Cu). The anode electrode 40 may have a multilayer structure of different metal films, such as Pt/Au, Pt/Al, Pd/Au, Pd/Al, Pt/Ti/Au, or Pd/Ti/Au.

The p-type semiconductor layer 60 and metal layer 80 are formed into a double-ring shape in a plan view, and the p-type semiconductor layer 60 and metal layer 80 are stacked in this order on the flat upper surface 31 of the drift layer 30. As a result, the p-type semiconductor layer 60 forms pn-junction with the drift layer 30. Examples of the material of the p-type semiconductor layer 60 may include Si, GaAs, GaN, SiC, Ge, ZnSe, CdS, InP, SiGe, AlN, BN, AlGaN, NiO, Cu₂O, Ir₂O₃, Ag₂O. Specifically, for example, the material of the p-type semiconductor layer 60 may be p-type Si having an impurity concentration of about 1×10¹⁸ cm⁻³ and a thickness of about 200 nm.

The n-type semiconductor layer 70 is brought into Schottky contact with the anode electrode 40 and acts to reduce contact resistance between the anode electrode 40 and the p-type semiconductor layer 60 that could be caused as they contact directly with each other. The n-type semiconductor layer 70 also directly contacts the drift layer 30. In the example illustrated in FIGS. 1A and 1B, the n-type semiconductor layer 70 contacts the side surface of the p-type semiconductor layer 60 and the upper and side surfaces of the metal layer 80. The material of the n-type semiconductor layer 70 may be a semiconductor material having a small band gap and capable of obtaining both p- and n-conductive types (e.g., a material obtained by introducing an n-type dopant into the same material as the p-type semiconductor layer 60). Specifically, for example, the material of the n-type semiconductor layer 70 may be n-type Ge or n-type Si having an impurity concentration of about 1×10¹⁵ cm⁻³ and a thickness of about 200 nm.

The metal layer 80 is positioned between the p-type semiconductor layer 60 and the n-type semiconductor layer 70 and acts to prevent formation of a depletion layer due to direct contact between the p-type semiconductor layer 60 and the n-type semiconductor layer 70. The material of the metal layer 80 may be Al, Pt, Pd, or the like. For example, when the n-type semiconductor layer 70 and the p-type semiconductor layer 60 are made of n-type Si and p-type Si, respectively, the metal layer 80 may be made of Al having a thickness of about 100 nm.

There is formed, on the back surface 22 of the semiconductor substrate 20, a cathode electrode 50 which is brought into ohmic contact with the semiconductor substrate 20. The cathode electrode 50 may have a multilayer structure of different metal films, such as Ti/Au or Ti/Al.

When a forward voltage is applied to the junction barrier Schottky diode 1 according to the present embodiment, three current paths from the anode electrode 40 to the drift layer 30 are formed. The first current path (“P1” in FIG. 1B) is a path along which current directly flows from the anode electrode 40 to the drift layer 30 without passing through the p-type semiconductor layer 60 and n-type semiconductor layer 70. The second current path (“P2” in FIG. 1B) is a path along which current passes through the n-type semiconductor layer 70, metal layer 80, and p-type semiconductor layer 60. The third current path (“P3” in FIG. 1B) is a path along which current only passes through the n-type semiconductor layer 70 without passing through the p-type semiconductor layer 60.

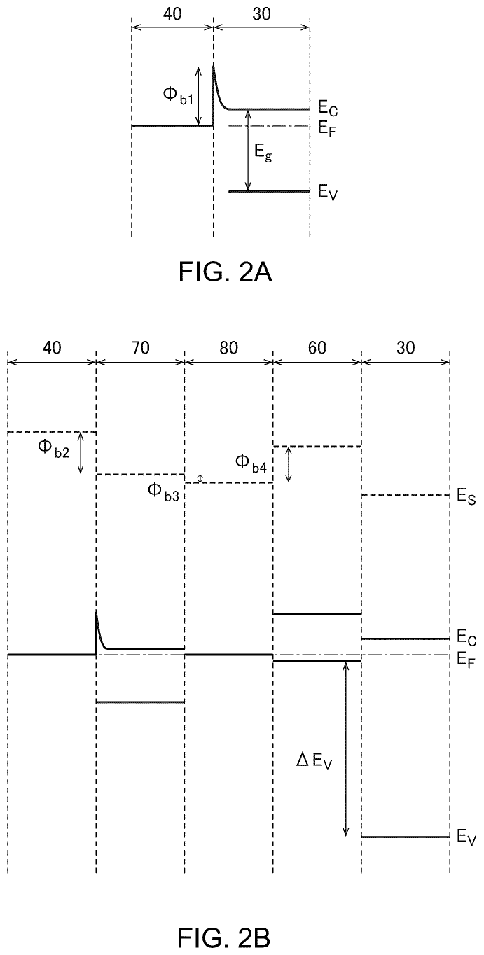

FIGS. 2A and 2B are energy band diagrams of the junction barrier Schottky diode 1 according to the present embodiment. FIG. 2A illustrates an energy band along the first current path P1, and FIG. 2B illustrates an energy band along the second current path P2.

As illustrated in FIG. 2A, the first current path P1, along which the anode electrode 40 and drift layer 30 are brought into Schottky contact with each other, functions as a Schottky barrier diode. Thus, the first current path P1 is thus turned ON first upon application of a forward voltage due to a low forward voltage and a high switching speed. The height of a Schottky barrier between the anode electrode 40 and drift layer 30 is Φ_{b1}. In FIGS. 2A and 2B, E_{F} denotes the Fermi level, E_{C} denotes a conduction band lower end level, E_{V} denotes a valence band upper end level, and E_{g} denotes an energy band gap.

On the other hand, as illustrated in FIG. 2B, the second current path P2 includes the n-type semiconductor layer 70, metal layer 80, and p-type semiconductor layer 60 positioned between the anode electrode 40 and the drift layer 30. Thus, when a higher forward voltage is applied after current flows along the first current path P1, the second current path P2 is turned ON. This significantly reduces an ON-resistance. Here, E_{S} is the vacuum level.

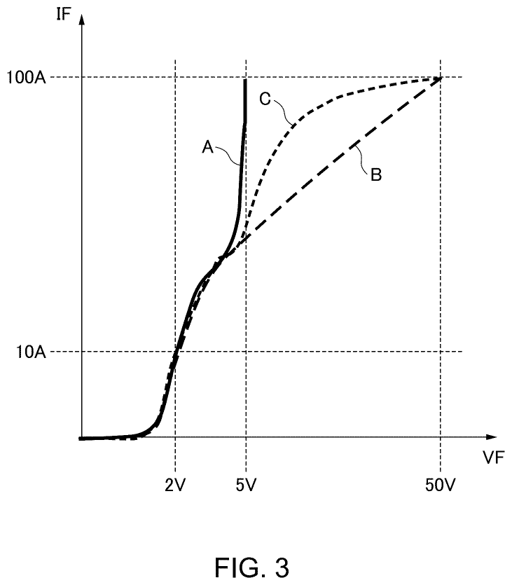

FIG. 3 is a graph illustrating the relation between a forward voltage VF and a forward current IF. In the graph, the sign A denotes characteristics of the junction barrier Schottky diode 1 according to the present embodiment, and the sign B denotes characteristics of a common Schottky barrier diode. As illustrated in FIG. 3, in a common Schottky barrier diode, a voltage of about 50 V is generated upon flowing of a sudden large current (surge current) of, e.g., 100 A, causing burning-out due to a large amount of heat generation. On the other hand, in the junction barrier Schottky diode 1 according to the present embodiment, even when a surge voltage of 100 A flows, a voltage to be generated can be reduced to about 5 V due to turning-ON of the second current path P2.

In addition, in the present embodiment, the n-type semiconductor layer 70 and metal layer 80 are disposed in this order between the anode electrode 40 and the p-type semiconductor layer 60. As illustrated in FIG. 2B, the vacuum level energy difference between the anode electrode 40 and the n-type semiconductor layer 70 is Φ_{b2}, the vacuum level energy difference between the n-type semiconductor layer 70 and the metal layer 80 is Φ_{b3}, the vacuum level energy difference between the metal layer 80 and the p-type semiconductor layer 60 is Φ_{b4}, and the energy difference between the valence band upper end level of the p-type semiconductor layer 60 and the valence band upper end level of the drift layer 30 is ΔE_{V}. Further, in the present embodiment, since the p-type semiconductor layer 60 contacts the anode electrode 40 not directly but through the n-type semiconductor layer 70 and metal layer 80, a resistance value between the anode electrode 40 and the p-type semiconductor layer 60 is reduced. As a result, surge resistance increases as compared with when the n-type semiconductor layer 70 and metal layer 80 do not exist.

When n-type Si, Al, and p-type Si are used for the n-type semiconductor layer 70, the metal layer 80, and the p-type semiconductor layer 60, respectively, the energy difference Φ_{b2} becomes about 0.9 eV, the energy difference Φ_{b3} becomes about 0.1 eV, the energy difference Φ_{b4} becomes about 0.8 eV, and the energy difference ΔE_{V} becomes about 4.3 eV. Thus, a pair of the n-type semiconductor layer 70 and metal layer 80, and a pair of the metal layer 80 and p-type semiconductor layer 60 each make ohmic contact with each other. On the other hand, when the n-type semiconductor layer 70 and metal layer 80 are not provided to fail to make ohmic contact between the anode electrode 40 and the p-type semiconductor layer 60, a relatively large voltage may be generated by the surge current as indicated by the characteristic curve C in the graph of FIG. 3.

Further, as illustrated in FIG. 1B, in the junction barrier Schottky diode 1 according to the present embodiment, the third current path P3 exists. The third current path P3 is a path along which current flows from the anode electrode 40 to the drift layer 30 through the n-type semiconductor layer 70 and is turned ON at substantially the same time as the first current path P1. Since the third current path P3 does not include the p-type semiconductor layer 60, the resistance value thereof is equivalent to that of the first current path P1.

As described above, in the junction barrier Schottky diode 1 according to the present embodiment, the n-type semiconductor layer 70 and metal layer 80 are interposed between the anode electrode 40 and the p-type semiconductor layer 60, so that a resistance value between the anode electrode 40 and the p-type semiconductor layer 60 is reduced, whereby large surge resistance can be obtained. Further, in the present embodiment, there is formed the third current path P3 that does not pass through the p-type semiconductor layer 60, so that the ON-resistance can be further reduced. Furthermore, the p-type semiconductor layer 60, metal layer 80, and n-type semiconductor layer 70 are formed on the flat upper surface 31 of the drift layer 30, thus making the manufacturing process of the junction barrier Schottky diode simple.

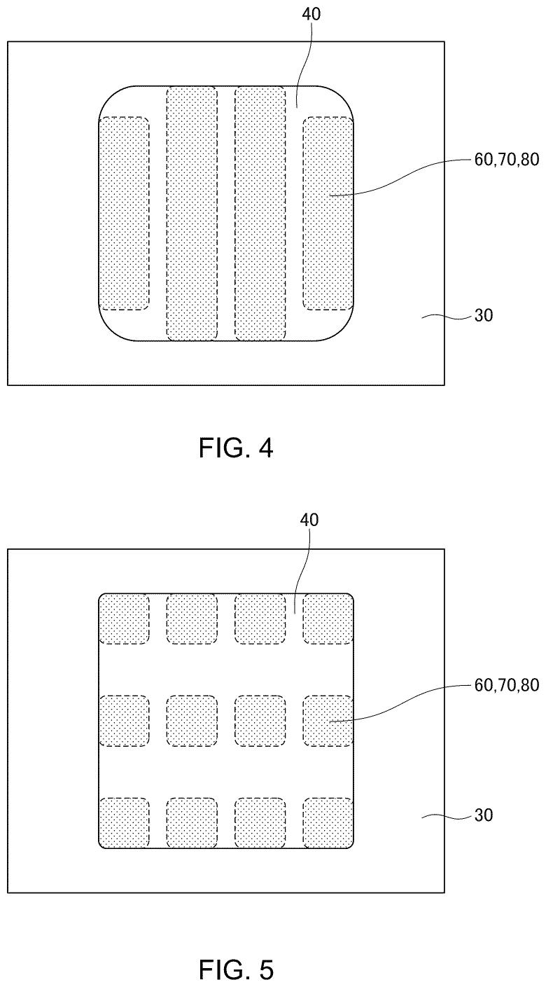

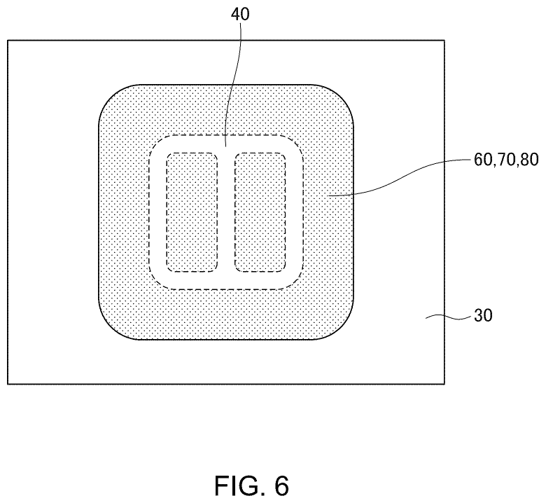

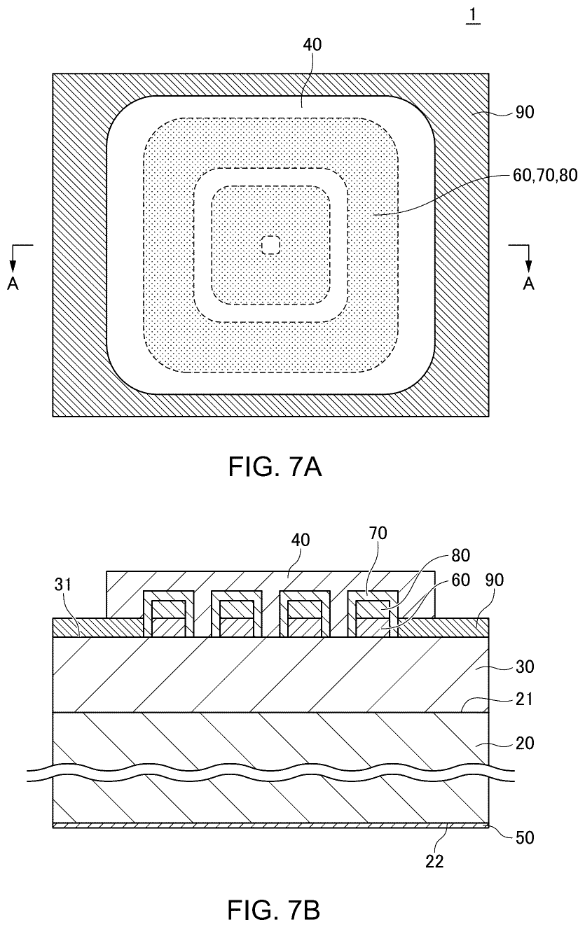

The shape of the p-type semiconductor layer 60 in a plan view is not limited to that illustrated in FIG. 1A. That is, in a plan view, the p-type semiconductor layer 60 may have a stripe shape as in a first modification illustrated in FIG. 4, a dotted shape as in a second modification illustrated in FIG. 5, and a shape formed by a combination of ring and stripe as in a third modification illustrated in FIG. 6. Further, as in a fourth modification illustrated in FIGS. 7A and 7B, the junction barrier Schottky diode 1 according to the present embodiment may be configured such that a field insulating film 90 is additionally provided on the upper surface 31 of the drift layer 30, on which the end portions of the anode electrode 40 are disposed. Employing such a field plate structure can relax an electric field to be applied to the drift layer 30.

### Second Embodiment

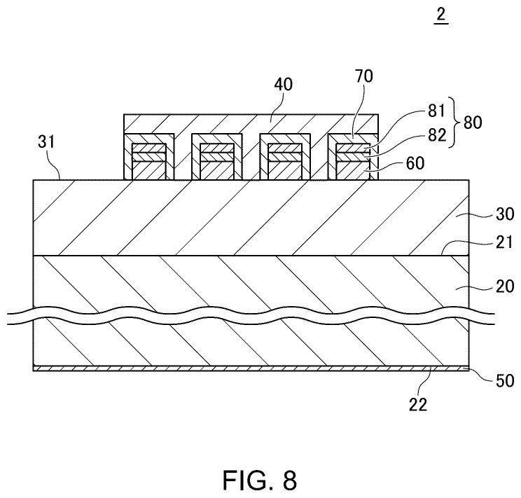

FIG. 8 is a schematic cross-sectional view illustrating the configuration of a junction barrier Schottky diode 2 according to a second embodiment of the present disclosure.

As illustrated in FIG. 8, the junction barrier Schottky diode 2 according to the second embodiment differs from the junction barrier Schottky diode 1 according to the first embodiment in that the metal layer 80 includes a first metal layer 81 and a second metal layer 82. Other basic configurations are the same as those of the junction barrier Schottky diode 1 according to the first embodiment, so the same reference numerals are given to the same elements, and overlapping description will be omitted.

In the present embodiment, as the material of the n-type semiconductor layer 70, Si, SiC, GaN, C, Ge, GaAs, BN, ALN, or the like can be used. As the material of the first metal layer 81, a material having a work function low enough to make ohmic contact with the n-type semiconductor layer 70 is selected. For example, when the n-type semiconductor layer 70 is made of Si or Sic, Al can be selected as the material of the first metal layer 81, and when the n-type semiconductor layer 70 is made of GaN, Ti can be selected as the material of the first metal layer 81. On the other hand, as the material of the second metal layer 82, a material having a work function high enough to make ohmic contact with the p-type semiconductor layer 60 is selected. As a first example, when the n-type semiconductor layer 70 and the p-type semiconductor layer 60 are made of n-type Si and p-type Si, respectively, Al having a thickness of about 100 nm can be selected as the material of the first metal layer 81, and Pt having a thickness of 100 nm can be selected as the material of the second metal layer 82. As a second example, when the n-type semiconductor layer 70 and the p-type semiconductor layer 60 are made of n-type Si and p-type BN, respectively, Al can be selected as the material of the first metal layer 81, and Pd can be selected as the material of the second metal layer 82. In both the above first and second examples, Si having an impurity concentration of about 1×10¹⁶ cm⁻³ and a thickness of about 200 nm can be selected as the material of the n-type semiconductor layer 70.

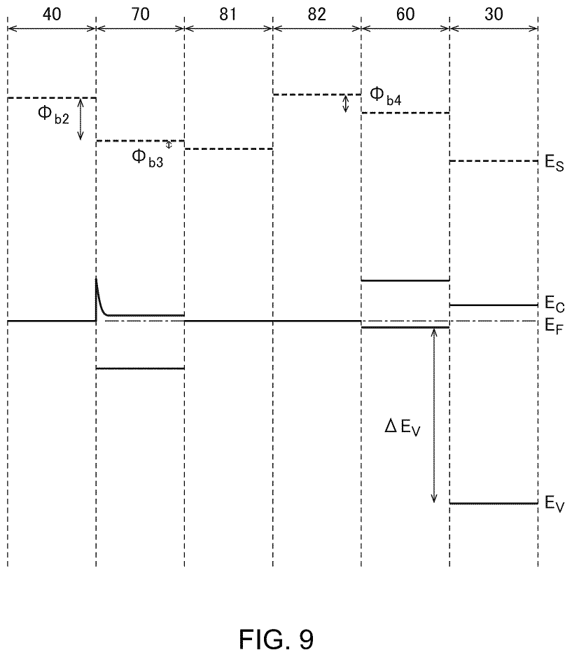

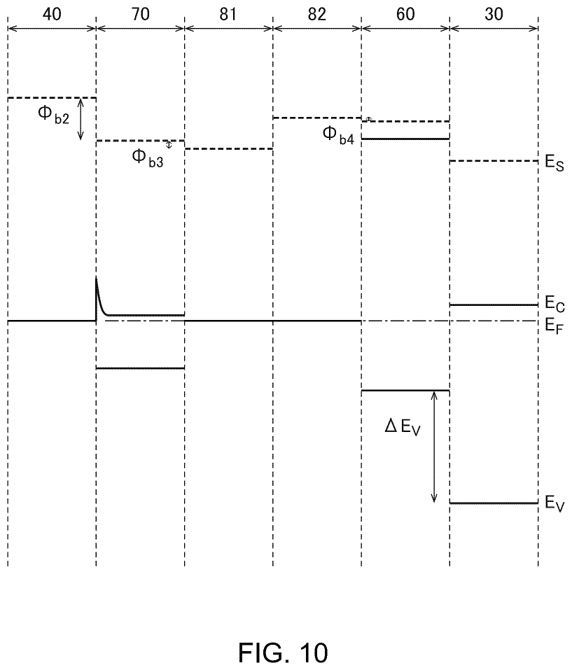

FIGS. 9 and 10 are energy band diagrams of the junction barrier Schottky diode 2 according to the present embodiment. FIG. 9 illustrates an energy band along the second current path P2 in the above first example, and FIG. 10 illustrates an energy band along the second current path P2 in the above second example.

As illustrated in FIG. 9, in the first example, the energy difference Φ_{b4} is reduced to about 0.3 eV. Further, as illustrated in FIG. 10, in the second example, the energy difference Φ_{b4} is reduced to about 0.1 eV. In the second example, the energy difference ΔE_{V} is about 2.8 eV. As described above, by forming the metal layer 80 into a two-layer structure of the first metal layer 81 made of a material that makes ohmic contact with the n-type semiconductor layer 70 and the second metal layer 82 made of a material that makes ohmic contact with the p-type semiconductor layer 60, the ON-resistance of the second current path P2 can further be reduced.

### Third Embodiment

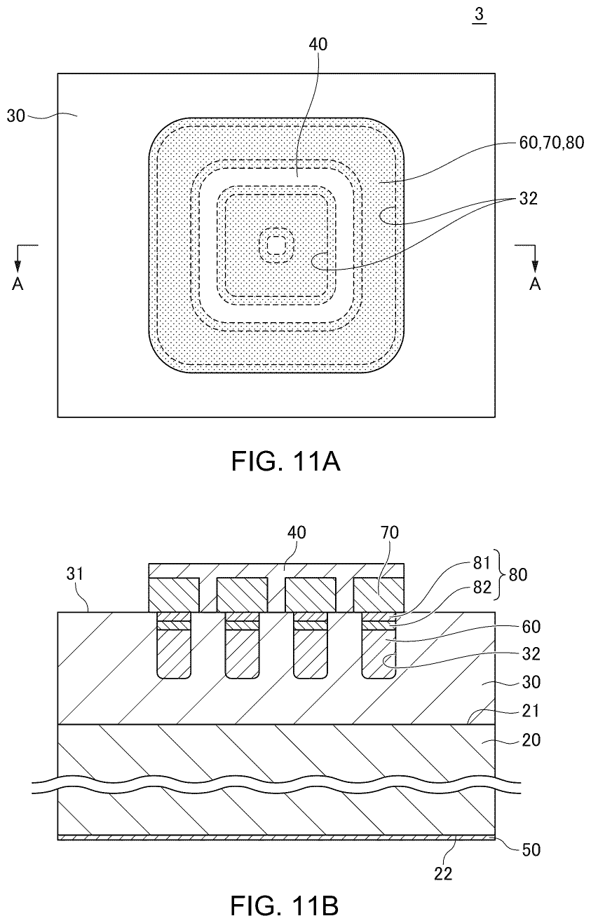

FIG. 11A is a schematic plan view illustrating the configuration of a junction barrier Schottky diode 3 according to a third embodiment of the present disclosure. FIG. 11B is a schematic cross-sectional view taken along the line A-A in FIG. 11A.

As illustrated in FIGS. 11A and 11B, the junction barrier Schottky diode 3 according to the third embodiment differs from the junction barrier Schottky diode 2 according to the second embodiment in that the p-type semiconductor layer 60 and metal layer 80 are filled in a trench 32 formed in the drift layer 30. Other basic configurations are the same as those of the junction barrier Schottky diode 2 according to the second embodiment, so the same reference numerals are given to the same elements, and overlapping description will be omitted.

The trench 32 extends from the upper surface 31 of the drift layer 30 to a depth that does not reach the semiconductor substrate 20 and has a double-ring shape in a plan view. For example, the depth of the trench 32 may be set to about 3 μm, and the width thereof may be set to about 1.5 μm. The trench 32 is filled with the p-type semiconductor layer 60 and metal layer 80. The n-type semiconductor layer 70 is formed outside the trench 32 at a position contacting the first metal layer 81 and drift layer 30.

As described above, in the junction barrier Schottky diode 3 according to the third embodiment, the p-type semiconductor layer 60 is filled in the trench 32 provided in the drift layer 30, thereby increasing contact area between the p-type semiconductor layer 60 and the drift layer 30, which in turn can further reduce the resistance value of the second current path P2.

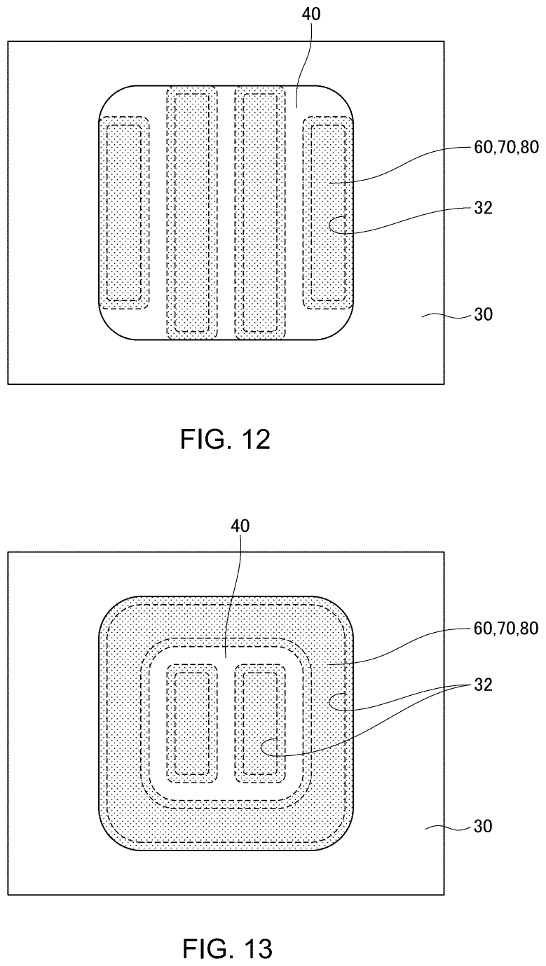

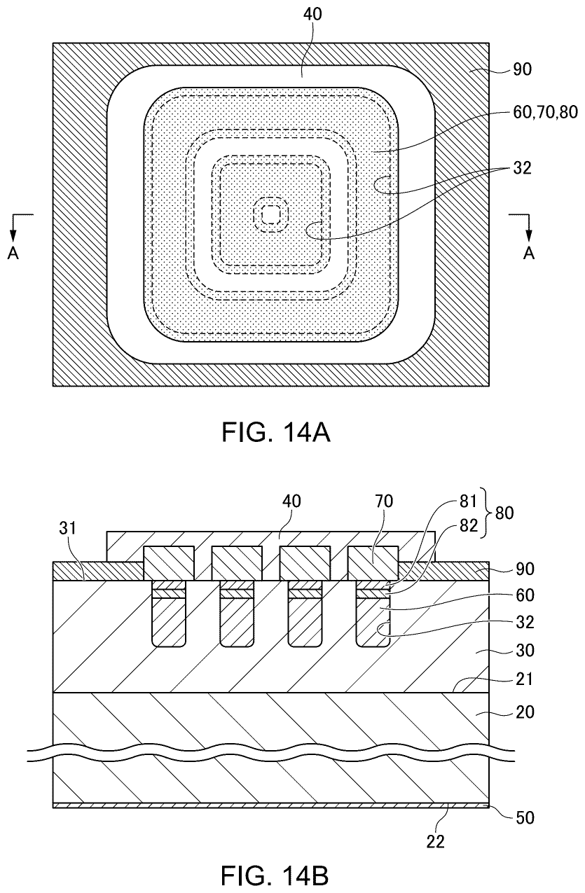

The shape of the trench 32 in a plan view is not limited to that illustrated in FIG. 11A. That is, as in a plan view, the trench 32 may have a stripe shape as in a fifth modification illustrated in FIG. 12 or a shape formed by a combination of ring and stripe as in a sixth modification illustrated in FIG. 13. Further, as in a seventh modification illustrated in FIGS. 14A and 14B, the junction barrier Schottky diode 3 according to the present embodiment may be configured such that a field insulating film 90 is additionally provided on the upper surface 31 of the drift layer 30, on which the end portions of the anode electrode 40 are disposed. Employing such a field plate structure can relax an electric field to be applied to the drift layer 30.

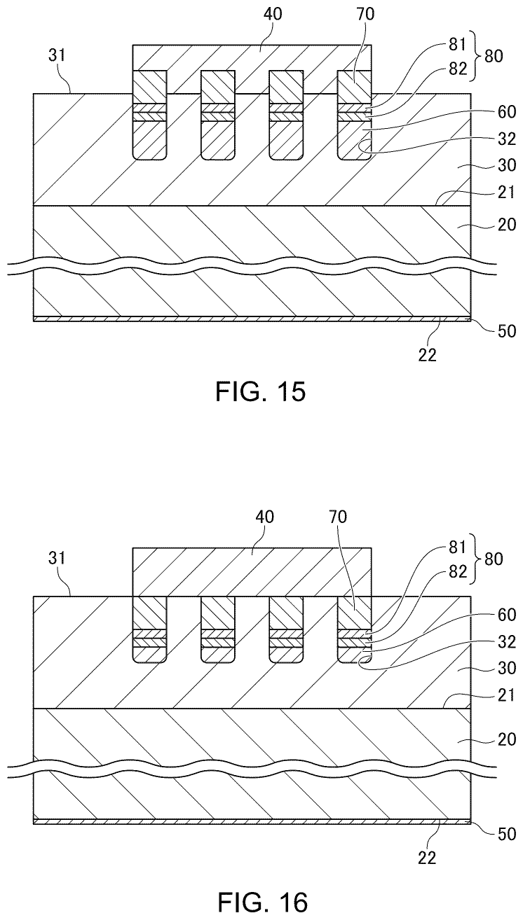

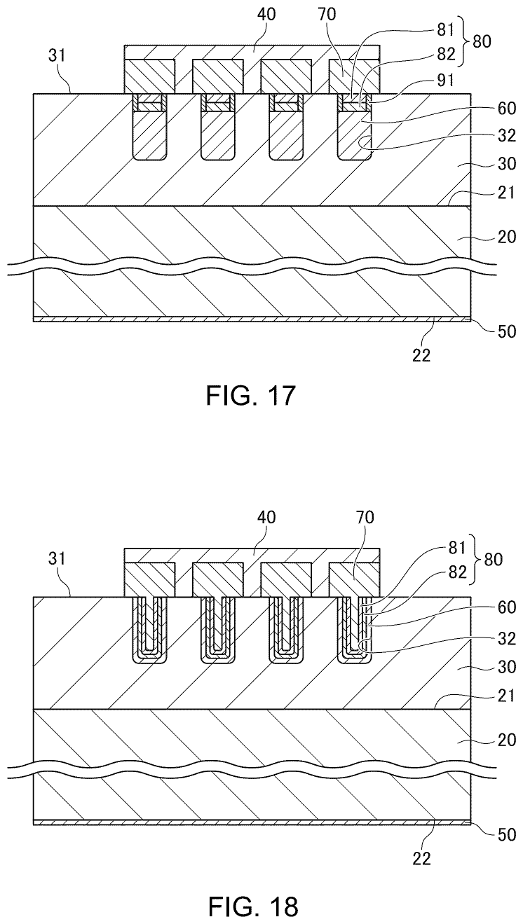

Further, the n-type semiconductor layer 70 may partially be filled in the trench 32 as in an eighth modification illustrated in FIG. 15, or may completely be filled in the trench 2 as in a ninth modification illustrated in FIG. 16. As described above, when at least a part of the n-type semiconductor layer 70 is filled in the trench 32, contact area between the n-type semiconductor layer 70 and the drift layer 30 increases to thereby further reduce the resistance value of the third current path P3. Further, as in a tenth modification illustrated in FIG. 17, an insulating film 91 may be provided between the metal layer 80 and the drift layer 30.

Further, as in an eleventh modification illustrated in FIG. 18, a configuration may be possible in which the p-type semiconductor layer 60 is provided along the inner wall of the trench 32, and the metal layer 80 is provided between the outer wall of the n-type semiconductor layer 70 filled in the trench 32 and the inner wall of the p-type semiconductor layer 60. This increases contact area between the p-type semiconductor layer 60 and the drift layer 30 and increases the surface area of the metal layer 80, thereby making it possible to further reduce the resistance value of the second current path P2.

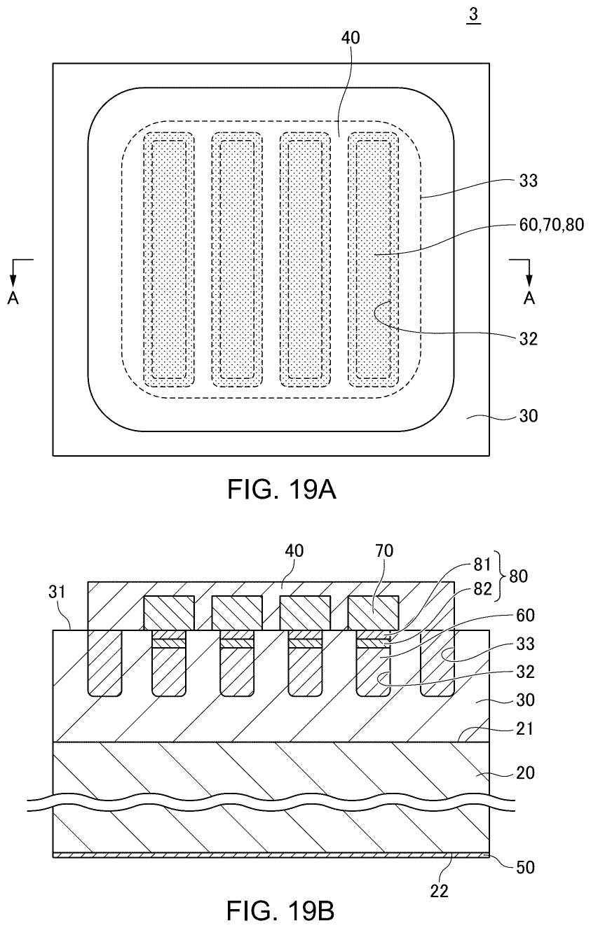

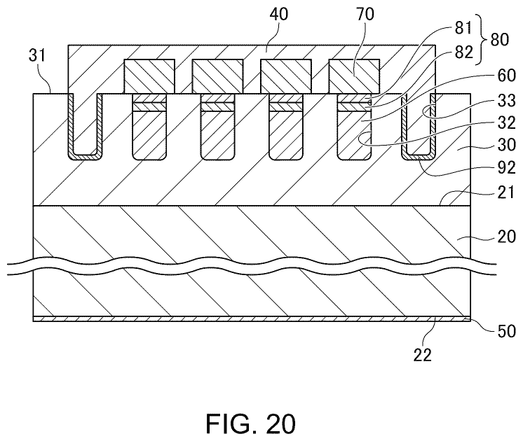

Further, as in a twelfth modification illustrated in FIGS. 19A and 19B, a configuration may be possible in which an outer peripheral trench 33 surrounding the trench 32 is provided in the drift layer 30, and the p-type semiconductor layer 60 contacting the anode electrode 40 is filled in the outer peripheral trench 33. Alternatively, as in a thirteenth modification illustrated in FIG. 20, a configuration may be possible in which the inner wall of the outer peripheral trench 33 is covered with an insulating film 92, and the anode electrode 40 is filled in the outer peripheral trench 33. Providing the thus formed outer peripheral trench 33 can relax an electric field to be concentrated on the bottom portion of the trench 32.

While the embodiments of the present disclosure have been described, the present disclosure is not limited to the above embodiment, and various modifications may be made within the scope of the present disclosure, and all such modifications are included in the present disclosure.

The technology according to the present disclosure includes the following configuration examples but not limited thereto.

A junction barrier Schottky diode according to the present disclosure includes: a semiconductor substrate; a drift layer provided on the semiconductor substrate; an anode electrode and a p-type semiconductor layer each contacting the drift layer; an n-type semiconductor layer contacting the anode electrode and the drift layer; a metal layer provided between the n-type semiconductor layer and the p-type semiconductor layer; and a cathode electrode contacting the semiconductor substrate.

According to the present disclosure, there is provided the n-type semiconductor layer that contacts the anode electrode and drift layer, so that the n-type semiconductor layer functions as a current path. This can reduce an ON-resistance during a time before a forward current flows in a pn-junction part. In addition, the anode electrode and p-type semiconductor layer are not directly contact each other, but the n-type semiconductor layer and metal layer are interposed therebetween. This reduces the resistance value of a current path that passes through the p-type semiconductor layer.

In the present disclosure, the metal layer may include a first metal layer which makes ohmic contact with the n-type semiconductor layer and a second metal layer which makes ohmic contact with the p-type semiconductor layer. This can reduce resistance between the metal layer and the n-type semiconductor layer and between the metal layer and the p-type semiconductor layer.

In the present disclosure, the p-type semiconductor layer and the metal layer may be stacked in this order on a flat surface of the drift layer, and the n-type semiconductor layer may cover a surface of a stacked body of the p-type semiconductor layer and the metal layer. This makes the manufacturing process of the junction barrier Schottky diode simple.

In the present disclosure, the drift layer may have a trench, and at least a part of the p-type semiconductor layer may be embedded in the trench. This can increase contact area between the p-type semiconductor layer and the drift layer. In this case, at least a part of the n-type semiconductor layer may be embedded in the trench. This can increase contact area between the n-type semiconductor layer and the drift layer. Further, in this case, the p-type semiconductor layer may be provided along an inner wall of the trench, and the metal layer may be provided between an inner wall of the p-type semiconductor layer and an outer wall of the n-type semiconductor layer. This can increase the surface area of the metal layer.

As described above, according to the present disclosure, it is possible to reduce the ON-resistance of a junction barrier Schottky diode.

What is claimed is:

1. A junction barrier Schottky diode comprising:
a semiconductor substrate;
a drift layer provided on the semiconductor substrate;
an anode electrode and a p-type semiconductor layer each contacting the drift layer;
an n-type semiconductor layer contacting the anode electrode and the drift layer;
a metal layer provided between the n-type semiconductor layer and the p-type semiconductor layer; and
a cathode electrode contacting the semiconductor substrate.

2. The junction barrier Schottky diode as claimed in claim 1, wherein the metal layer includes a first metal layer which makes ohmic contact with the n-type semiconductor layer and a second metal layer which makes ohmic contact with the p-type semiconductor layer.

3. The junction barrier Schottky diode as claimed in claim 1,
wherein the p-type semiconductor layer and the metal layer are stacked in this order on a flat surface of the drift layer, and
wherein the n-type semiconductor layer covers a surface of a stacked body of the p-type semiconductor layer and the metal layer.

4. The junction barrier Schottky diode as claimed in claim 1,
wherein the drift layer has a trench, and
wherein at least a part of the p-type semiconductor layer is embedded in the trench.

5. The junction barrier Schottky diode as claimed in claim 4, wherein at least a part of the n-type semiconductor layer is embedded in the trench.

6. The junction barrier Schottky diode as claimed in claim 5,
wherein the p-type semiconductor layer is provided along an inner wall of the trench, and
wherein the metal layer is provided between an inner wall of the p-type semiconductor layer and an outer wall of the n-type semiconductor layer.
